(19) United States
(12) Patent Application Publication
(10) Pub. No.: US 2024/0176231 A1
(43) Pub. Date: May 30, 2024

(54) IMPRINT APPARATUS, ARTICLE MANUFACTURING METHOD, DETERMINATION METHOD, AND RECORDING MEDIUM

(71) Applicant: CANON KABUSHIKI KAISHA, Tokyo (JP)

(72) Inventor: KEIJI YAMASHITA, Tochigi (JP)

(21) Appl. No.: 18/523,745

(22) Filed: Nov. 29, 2023

(30) Foreign Application Priority Data
Nov. 30, 2022 (JP) 2022-190922

(51) Int. Cl. G03F 7/00; G03F 9/00

(52) U.S. Cl. CPC G03F 7/0002; G03F 9/7042

(57) ABSTRACT

An imprint apparatus that performs an imprint process of forming a pattern on an imprint material supplied on a substrate by bringing the imprint material into contact with a mold. The imprint apparatus includes a holding unit configured to hold the substrate, a supply unit configured to supply a droplet of the imprint material to the substrate in a partial region, the partial region including an edge of the substrate and with which a part of a pattern region of the mold is to come into contact in the imprint process, and a control unit configured to determine a position or an amount of the droplet of the imprint material to be supplied to the partial region, based on measurement data on a surface height of the partial region in a state in which the holding unit holds the substrate.

### BACKGROUND

### Field

The present disclosure relates to an imprint apparatus, an article manufacturing method, a determination method, and a recording medium.

### Description of the Related Art

An imprint apparatus forms a pattern on a resin by bringing a pattern region of a mold into contact with the resin supplied to a substrate, curing the resin, and separating the mold from the resin.

Japanese Patent Application Laid-Open No. 2013-175595 discusses a configuration in which a substrate supporting unit disposed in a substrate holding apparatus is vertically driven in such a manner that a local distortion generated in a substrate is adjusted, to correct the distortion of the substrate.

A substrate on which a pattern has been formed by a lithography process is sometimes in a deformed state due to a deformation caused by a subsequent manufacturing process or a step formed in a vicinity of an outer periphery of the substrate. In addition, a structure and a suction pressure of a chuck for holding substrates may cause a local distortion in a substrate, which results in unevenness of a surface of the substrate that has been held by the chuck.

### SUMMARY

According to an aspect of the present disclosure, an imprint apparatus that performs an imprint process of forming a pattern on an imprint material supplied on a substrate by bringing the imprint material into contact with a mold, the imprint apparatus including a holding unit configured to hold the substrate, a supply unit configured to supply a droplet of the imprint material to the substrate in a partial region, the partial region including an edge of the substrate and with which a part of a pattern region of the mold is to come into contact in the imprint process, and a control unit configured to determine a position or an amount of the droplet of the imprint material to be supplied to the partial region, based on measurement data on a surface height of the substrate in the partial region in a state in which the holding unit holds the substrate, wherein the supply unit supplies the droplet of the imprint material to the partial region, based on the determined position or the determined amount of the droplet of the imprint material, and wherein the imprint apparatus forms the pattern on the imprint material by bringing the imprint material supplied to the partial region into contact with the mold.

Further features of the present disclosure will become apparent from the following description of exemplary embodiments with reference to the attached drawings.

### BRIEF DESCRIPTION OF THE DRAWINGS

FIG. 1 is a schematic view illustrating an imprint apparatus according to a first exemplary embodiment.

FIG. 2 is a flowchart illustrating an imprint process.

FIG. 3 is a diagram illustrating a shot layout.

FIGS. 4A and 4B are diagrams illustrating defects that occur in the imprint process.

FIG. 5 is a flowchart illustrating the imprint process according to the first exemplary embodiment.

FIG. 6 is a graph illustrating a relationship between a substrate height and a suction pressure.

FIG. 7 is a diagram illustrating a relationship between a shape of a resin and an elapsed time from when the resin is supplied.

FIG. 8 is a flowchart illustrating an imprint process according to a second exemplary embodiment.

FIGS. 9A to 9F are schematic diagrams illustrating a method for manufacturing an article.

### DESCRIPTION OF THE EMBODIMENTS

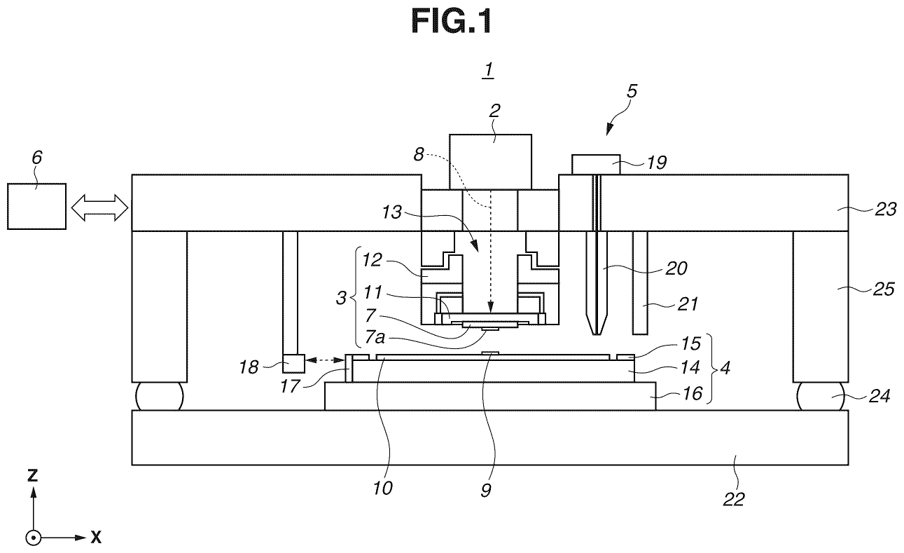

An imprint apparatus according to a first exemplary embodiment will be described. FIG. 1 is a schematic view illustrating a configuration of an imprint apparatus 1 according to the present exemplary embodiment. The imprint apparatus 1 is used to manufacture devices, such as a semiconductor device. The imprint apparatus 1 forms a resin pattern on a substrate by bringing an uncured resin supplied to the substrate into contact with a mold (template). In the present exemplary embodiment, the imprint apparatus 1 uses a photo-curing method. In the drawings described below, a Z-axis is parallel to an optical axis of an illumination system which irradiates a resin on a substrate with ultraviolet light, and an X-axis and a Y-axis orthogonal to each other are in a plane perpendicular to the Z-axis. The imprint apparatus 1 includes a light irradiation unit 2, a mold holding mechanism 3, a substrate stage 4, a supply unit 5, and a control unit 6.

The light irradiation unit 2 irradiates a mold 7 and a resin on a substrate with ultraviolet light 8. The light irradiation unit 2 includes a light source and an illumination optical system that adjusts the ultraviolet light 8 to be emitted from the light source to light appropriate for imprinting and irradiates the mold 7 with the ultraviolet light 8. As the light source, a lamp, such as a mercury lamp, can be used. However, the light source is not particularly limited to a specific light source as long as the light source emits light having a wavelength which passes through the mold 7 and cures a resin (ultraviolet curable resin) 9 to be described below. The illumination optical system may include various components including a lens, a mirror, an aperture, a shutter for changing an operation state between irradiation and light blocking. In the present exemplary embodiment, the light irradiation unit 2 is disposed to adopt the photo-curing method. However, for example, in a case where a thermal curing method is used, a heat source unit for curing a thermosetting resin is disposed instead of the light irradiation unit 2.

The mold 7 has a polygonal outer peripheral shape (desirably, rectangular or square). A surface of the mold 7 that faces a substrate 10 includes a pattern portion 7a (pattern region) in which an uneven pattern to be transferred, such as a circuit pattern, is three dimensionally formed. Among pattern sizes that vary in accordance with articles to be manufactured, there are patterns with sizes even in ten and several nanometers. The material of the mold 7 is desirably capable of transmitting the ultraviolet light 8 and has a low thermal expansion coefficient, examples of which include quartz. Further, the mold 7 may have a cavity having a circular planar shape and a certain depth on a surface that is irradiated with the ultraviolet light 8.

The mold holding mechanism 3 includes a mold chuck 11 for holding the mold 7, a mold driving mechanism 12 for movably holding the mold chuck 11, and a magnification adjustment mechanism for adjusting a shape of the mold 7 (pattern portion 7a). The mold chuck 11 holds the mold 7 by attracting, with a vacuum suction force or an electrostatic force, an outer peripheral region on an irradiation surface of the mold 7 to be irradiated with the ultraviolet light 8. For example, in a case of using the vacuum suction force to hold the mold 7, the mold chuck 11 is connected to a vacuum pump (not illustrated) installed outside, and the mold chuck 11 adjusts the vacuum suction force (holding force) with respect to the mold 7 by appropriately adjusting a suction pressure using exhaust of the vacuum pump. The mold driving mechanism 12 moves the mold 7 in each axial direction to selectively press and separate the mold 7 against and from the resin 9 on the substrate 10. Examples of a power source which is able to be employed in the mold driving mechanism 12 include a linear motor and an air cylinder. The mold driving mechanism 12 may be configured with a plurality of driving systems, such as a coarse movement driving system and a fine movement driving system, to perform high-precision positioning of the mold 7. Furthermore, the mold driving mechanism 12 may be configured to have a position adjustment function for adjusting the position of the mold 7 not only in the Z-axis direction but also in the X-axis direction and the Y-axis direction, or a θ (rotation about the Z-axis) direction, a tilt function for adjusting the tilt of the mold 7, and the like. Each operation of pressing and separating in the imprint apparatus 1 may be realized by movement of the mold 7 in the Z-axis direction, by a movement of the substrate stage 4 in the Z-axis direction, or by a relative movement between the mold 7 and the substrate stage 4. The position of the mold 7 when the mold driving mechanism 12 is driven is able to be measured with a position measurement unit, such as an optical displacement meter which measures the distance between the mold 7 and the substrate 10. The magnification adjustment mechanism disposed in the mold chuck 11 on a side for holding the mold 7 adjusts the shape of the mold 7 (pattern portion 7a) by mechanically applying an external force or a change in position to the side surface of the mold 7.

Further, the mold chuck 11 and the mold driving mechanism 12 have an opening region 13, which allows the ultraviolet light 8 emitted from the light irradiation unit 2 to travel toward the substrate 10, at the center portion (inside) in a planar direction. In some cases, the mold chuck 11 or the mold driving mechanism 12 includes a light transmitting member (for example, a glass plate) which seals a cavity surrounded by a part of the opening region 13 and the mold 7. In this case, the pressure in the cavity is adjusted by a pressure adjustment device (mold deformation unit) including a vacuum pump or the like. The pressure adjustment device bends the pattern portion 7a into a convex shape toward the substrate 10 and brings the pattern portion 7a into contact with the resin 9 from the central portion of the pattern portion 7a. For example, when the mold 7 and the resin 9 are pressed against each other, the pattern portion 7a is deformed into the convex shape toward the substrate 10 by the inner pressure of the cavity set to be higher than the outer pressure of the cavity. With the deformation, every corner of an uneven pattern of the pattern portion 7a is to be filled with the resin 9.

The substrate 10 is, for example, a single crystal silicon substrate, a silicon on insulator (SOI) substrate, or a glass substrate. In a plurality of pattern forming regions (shot regions) of the substrate 10, patterns (layers including patterns) of the resin 9 are formed by the pattern portion 7a. In some cases, patterns (substrate-side patterns) have already been formed in the pattern forming regions in a previous process before the substrate 10 is loaded into the imprint apparatus 1.

The substrate stage 4 movably holds the substrate 10, and performs, for example, alignment between the pattern portion 7a and the substrate-side pattern when the mold 7 and the resin 9 on the substrate 10 are pressed against each other. The substrate stage 4 includes a substrate chuck 14 for holding the substrate 10 by a suction force, an auxiliary member 15 disposed to surround an outer periphery of the substrate 10, and a stage driving mechanism 16 for mechanically holding the substrate chuck 14 and moving the substrate chuck 14 in each axial direction. The substrate chuck 14 (substrate holding unit) holds the substrate 10 by, for example, supporting the substrate 10 with a plurality of pins having the same height, and reducing the pressure of a space other than the pins using vacuum exhaust. The stage driving mechanism 16 is a power source with little vibration during its driving and at rest, and examples of the power source that can be employed in the present exemplary embodiment include a linear motor and a planar motor. The stage driving mechanism 16 may also be configured with a plurality of driving systems, such as a coarse movement driving system and a fine movement driving system, with respect to each direction of the X axis and the Y axis. Furthermore, the stage driving mechanism 16 may have a driving system for position adjustment in the Z-axis direction, a position adjustment function for adjusting the position of the substrate 10 in the θ direction, or a tilt function for adjusting the tilt of the substrate 10. The substrate stage 4 has, on its side surface, a plurality of reference mirrors 17 corresponding to the X, Y, and Z directions and ωx, ωy, and ωz directions. The imprint apparatus 1 includes a plurality of laser interferometers (position measurement mechanisms) 18, each corresponding to a different one of the reference mirrors 17, which measure the position of the substrate stage 4 by irradiating the reference mirrors 17 with beams of helium neon or the like. In FIG. 1, only one set of the reference mirror 17 and the laser interferometer 18 is illustrated. The laser interferometer 18 measures the position of the substrate stage 4 in real time, and the control unit 6 (to be described below) performs positioning control on the substrate 10 (substrate stage 4) based on a measurement value acquired in the measurement. The auxiliary member 15 has a surface height approximately equal to a height of the substrate 10 placed on the substrate chuck 14 and is utilized to prevent gas from entering an optical path between the reference mirror 17 and the laser interferometer 18.

The supply unit 5 is disposed in the vicinity of the mold holding mechanism 3 and supplies the resin 9 in an uncured state to a shot region (substrate-side pattern) serving as a pattern forming region on the substrate 10. The resin 9 is an ultraviolet curable resin (photocurable resin, imprint material) that has a property of being cured by receiving the ultraviolet light 8, and is appropriately selected in accordance with various conditions, such as a semiconductor device manufacturing process. The supply unit 5 employs an ink jet method and includes a container 19 that stores the resin 9 in an uncured state and a droplet discharge unit 20 that discharges droplets of the resin 9. It is desirable that the container 19 should manage the resin 9 by keeping the inside thereof in an atmosphere which does not cause a curing reaction of the resin 9. The atmosphere is, for example, an atmosphere containing a slight amount of oxygen. In addition, it is desirable that the material of the container 19 should be a material that does not mix particles or chemical impurities into the resin 9. The droplet discharge unit 20 has, for example, a piezo-type discharge mechanism (inkjet head) including a plurality of discharge ports. The discharge amount of the resin 9 is able to be adjusted in the range of 0.1 picolitre (pL)/droplet to 10 pL/droplet, and usually, about 1 pL/droplet is used in many cases. The discharge amount of the resin 9 is determined based on a density of the pattern portion 7a and a desired residual layer thickness. The supply unit 5 distributes and supplies the resin 9 as droplets on the shot region based on an operation command issued from the control unit 6 and controls the positions where the droplets of the resin 9 are to be arranged, the amount of each droplet, and the like.

The control unit 6 controls operations and adjustments of each component of the imprint apparatus 1. The control unit 6 including, for example, a computer or a processing unit including a processor and a memory is connected to each component of the imprint apparatus 1 via a line and performs control of each component in accordance with a program or the like. The control unit 6 according to the present exemplary embodiment controls at least operations of the supply unit 5, the substrate stage 4, a rotation mechanism (to be described below), and the like. The control unit 6 may be configured in a housing of the imprint apparatus 1 or may be configured separately from the imprint apparatus 1 (in a different housing).

The imprint apparatus 1 also includes an alignment measurement system 21 which measures alignment marks formed on the substrate 10. The imprint apparatus 1 also includes a base 22 that forms a reference plane and on which the substrate stage 4 is placed, a bridge base 23 that fixes the mold holding mechanism 3, and a column 25 that extends from the base 22 and supports the bridge base 23 via a vibration isolator 24 for eliminating vibration from a floor surface. Furthermore, the imprint apparatus 1 may include a mold conveyance mechanism which loads and unloads the mold 7 at the outside of the imprint apparatus 1 and the mold holding mechanism 3, a substrate conveyance mechanism which loads and unloads the substrate 10 at the outside of the imprint apparatus 1 and the substrate stage 4, and the like.

An imprint method (imprint process) performed by the imprint apparatus 1 will be described.

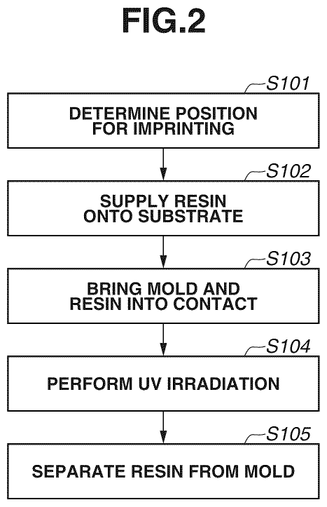

FIG. 2 is a diagram illustrating a flowchart of a basic imprint process. First, the control unit 6 causes a substrate conveyance apparatus to place and fix the substrate 10 on the substrate stage 4. Next, the control unit 6 causes the alignment measurement system 21 to sequentially measure the alignment marks on the substrate 10 while driving the stage driving mechanism 16 to appropriately change the position of the substrate 10, whereby the position of the substrate 10 is detected with high accuracy. The control unit 6 calculates each transfer coordinate from a result of the detection, and sequentially forms a pattern for each predetermined shot based on a result of the calculation (step-and-repeat). As a procedure for pattern formation for one shot, in step S101, the control unit 6 determines a shot region of the substrate 10 to which the resin 9 is to be supplied. Then, the stage driving mechanism 16 positions the determined shot region below the discharge port of the droplet discharge unit 20. In step S102, the supply unit 5 supplies the resin 9 to the shot region positioned in step S101. Next, the control unit 6 causes the stage driving mechanism 16 to move and position the substrate 10 so that the shot region is at a pressing position immediately below the pattern portion 7a of the mold 7. Next, the control unit 6 performs position alignment between the pattern portion 7a and the substrate-side pattern in the shot region, magnification adjustment of the pattern portion 7a by the magnification adjustment mechanism, and the like. In step S103 as an imprinting process, the mold driving mechanism 12 is driven to bring the pattern portion 7a into contact with the resin 9 on the shot region, to perform imprinting. By the contact and imprinting, an uneven pattern of the pattern portion 7a is filled with the resin 9. The control unit 6 is able to determine completion of the imprinting with a load sensor disposed inside the mold holding mechanism 3. In the completion state of imprinting, in step S104 as a curing process, the light irradiation unit 2 irradiates the resin 9 with the ultraviolet light 8 from the back surface (upper surface) of the mold 7 for a predetermined time to cure the resin 9 with the ultraviolet light 8 transmitted through the mold 7. After the resin 9 is cured, in step S105 as a mold releasing process, the control unit 6 drives the mold driving mechanism 12 again to separate the pattern portion 7a from the substrate 10. As a result, a three-dimensional pattern (layer) corresponding to the uneven pattern of the pattern portion 7a is formed on the surface of the shot region on the substrate 10. The imprint apparatus 1 is able to form a plurality of resin patterns on one substrate 10 by performing the above-described series of imprint operations a plurality of times while changing the shot region by driving the substrate stage 4.

If air bubbles (air) are present in a gap between the mold 7 and the substrate 10 when the mold 7 is pressed against the resin 9 on the substrate 10 to fill the pattern portion 7a with the resin 9, an unfilled defect occurs in the formed pattern after curing. Thus, the air in the gap between the mold 7 and the substrate 10 may be replaced with a gas having at least one of high solubility and high diffusibility with respect to the resin 9. Examples of the gas having such a property include helium.

As a gas replacement method, a method of increasing a helium concentration around the mold 7 with helium issued from a gas supply port disposed at least around the mold 7 may be used. With this method using a diffusion effect of helium itself, replacement of the air in the gap between the mold 7 and the substrate 10 is performed by helium continuously issuing for a predetermined period. However, in such a gas replacement method, a certain waiting time is required until the helium concentration in the gap between the mold 7 and the substrate 10 reaches a sufficiently high level.

Since the certain waiting time adversely affects the productivity, it is necessary to shorten the waiting time as much as possible. Thus, a gas replacement method utilizing a gas flow occurring with the driving of the substrate stage 4, that is, a so-called Coandã effect, is effective.

Next, an imprint method for imprinting a peripheral region of the substrate 10 will be described in detail. In order to obtain as many patterns (chips, devices) as possible from one substrate 10, it is necessary to perform imprinting even on the peripheral region (partial region) including an edge of the substrate 10.

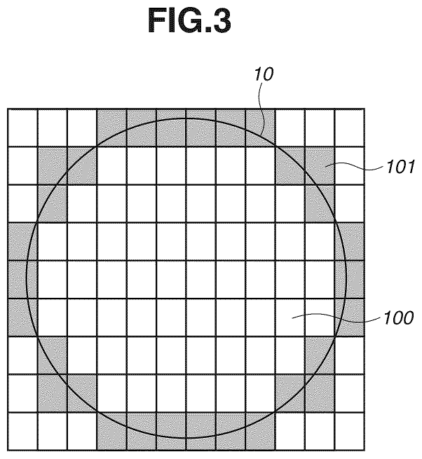

FIG. 3 is a diagram illustrating an entire layout of a shot layout. The shot layout includes a plurality of complete regions (full fields) 100 and a plurality of partial regions (partial fields, partial shots) 101. Each complete region 100 has an area that entirely overlaps with the pattern portion 7a of the mold 7, and the pattern portion 7a is completely transferred to the complete region 100. Each partial region 101 includes the edge of the substrate 10, which is indicated by a circle in FIG. 3, and has an area that overlaps with only a part of the pattern portion 7a. In the partial region 101 in the imprint process, only the part of the pattern portion 7a is brought into contact with and transferred to the resin 9 in the partial region 101.

The substrate 10 is held by the substrate chuck 14. As holding means, for example, vacuum suction is used to hold the substrate 10. Depending on a shape or a vacuum suction pressure of the substrate chuck 14, the substrate 10 may be bent. Further, because the substrate 10 to be subjected to the imprint process has undergone various kinds of preprocessing (for example, patterning by photolithography using light), a step may be formed in the vicinity of the outer periphery of the substrate 10.

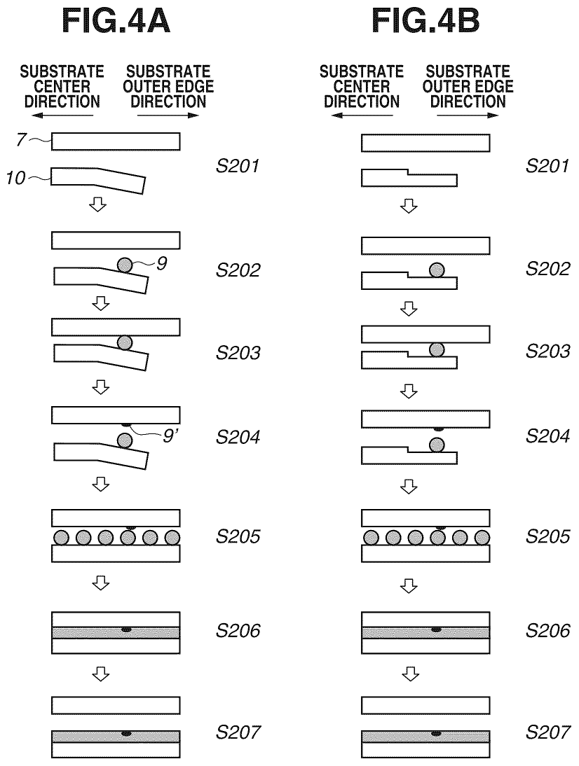

With reference to FIGS. 4A and 4B, a description will be given of a pattern defect caused by such a bend or a step. FIG. 4A illustrates a case where a bend occurs in the vicinity of the outer periphery of the substrate 10, and FIG. 4B illustrates a case where a step is formed in the vicinity of the outer periphery of the substrate 10. In step S201 in FIGS. 4A and 4B, a cross sectional view of the mold 7 and the partial region 101 before the imprint process is illustrated. The partial region 101 includes a region having a bend or a step. In step S202, the resin 9 is supplied to the partial region 101. In the diagrams illustrating step S202, only the resin 9 supplied to the region having the bend or the step is illustrated.

In step S203 as an imprinting process, the mold 7 comes into contact with the resin 9 supplied to the region having the bend or the step. In this process, even when the mold 7 and the resin 9 are in contact with each other, if contact between the mold 7 and the resin 9 is insufficient, the resin 9 remains in the mold 7 as a resin 9′ in a liquid state as illustrated in step S204. In a subsequent curing process, the resin 9′ remaining on the mold 7 is cured. The imprint process for the next shot region is performed while the resin 9′ remains on the surface of the mold 7 without volatilizing. Steps S205 to S207 illustrate a process in which the imprint process is performed on the next shot region after the imprint process performed on the partial region 101. In step S205, the resin 9 is supplied to the complete region 100 of the next shot region. In this process, the resin 9′ cured in the curing process remains in the mold 7. Through an imprinting process, a curing process, and a mold releasing process in step S206, a state illustrated in step S207 is obtained. The resin 9′ remaining in the mold 7 is taken into the resin 9 in the imprinting process, is separated from the mold 7 as illustrated in step S207, and is contained in the resin 9. As a result, the resin 9′ which has peeled off from the mold 7 and is contained in the resin 9 on the substrate is detected as a pattern defect.

In view of the above-described issue, in the present exemplary embodiment, the position and the amount of the resin 9 to be supplied is determined based on the surface height of the substrate 10, and the imprint process is performed. More specifically, the surface height of the substrate 10 is measured in a state in which the substrate 10 is held by the substrate chuck 14, and the position and/or the amount of a droplet of the resin 9 to be supplied to the shot region is determined based on measurement data of the surface height. Then, based on the determined position and/or the determined amount of a droplet of the resin 9, a droplet of the resin 9 is supplied to the shot region, and the resin 9 supplied to the shot region is brought into contact with the mold 7 to form a pattern on the resin 9.

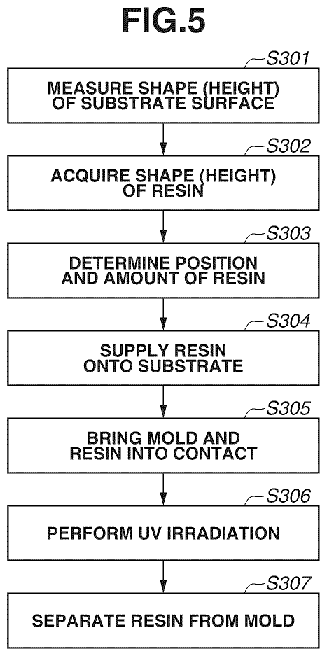

FIG. 5 is a flowchart illustrating the imprint process according to the present exemplary embodiment. While a description is given using an example case in which the shot region to be subjected to the imprint process is the partial region 101, the configuration is also applicable to the imprint process for the complete region 100.

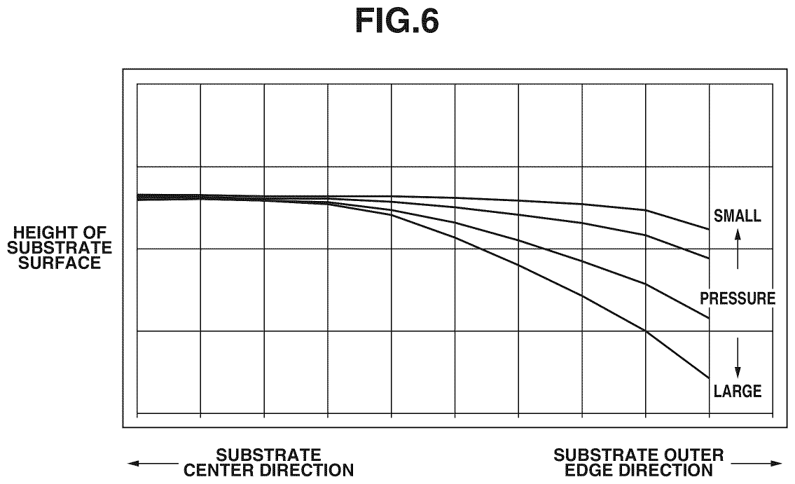

In step S301, a surface shape (height) of the partial region 101 of the substrate 10 is measured. The control unit 6 is able to acquire the surface shape by measuring the surface height of the partial region 101 at a plurality of positions. That is, information on the surface height includes information on the surface shape. In a state in which the substrate 10 is held by the substrate chuck 14, the surface shape of the substrate 10 is measured using a measurement unit. As means for measuring the surface shape (height), the alignment measurement system 21 may be used to measure the height of a region in the vicinity of the outer periphery of the substrate 10, or a measurement system for substrate shape measuring may be separately disposed. Alternatively, the imprint apparatus 1 may include a measurement station for measuring the surface shape of the substrate 10 to perform the measurement before the imprint process. FIG. 6 is a graph illustrating an example of measurement results of the surface height of the substrate 10 acquired by measuring an outer peripheral portion of the substrate 10. When the suction pressure of the substrate chuck 14 in the vicinity of the outer peripheral portion of the substrate 10 is increased, the surface of the substrate 10 is bent further downward, and the amount of the distortion decreases with a decrease in the suction pressure. The suction pressure of the substrate chuck 14 may vary depending on a shape of a pattern formed on the mold 7 and conditions (imprint conditions) of the imprint process (imprinting, curing, releasing, and the like).

In step S302, the control unit 6 acquires information on a shape (height and width) of a droplet of the resin 9.

The surface shape of the resin 9 is able to be acquired by measuring the surface height of the resin 9 at a plurality of positions.

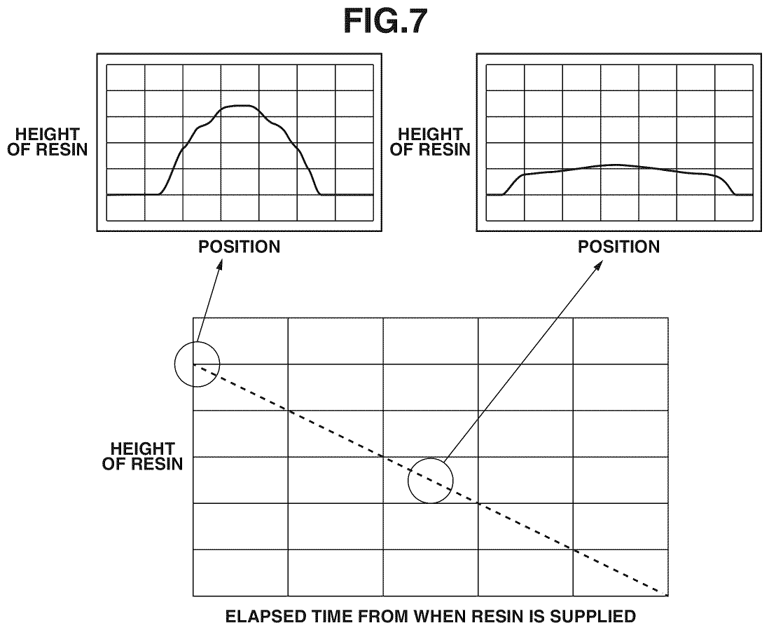

That is, information on the height of a droplet of the resin 9 includes information on the shape of a droplet of the resin 9. FIG. 7 is a diagram illustrating a relationship between the height of the resin 9 and an elapsed time from when the resin 9 is supplied. Immediately after the resin 9 is supplied to the substrate 10, the height of the resin 9 is large and the width of the resin 9 is small. As time elapses from when the resin 9 has been supplied, the resin 9 spreads out. Thus, the height of the resin 9 becomes small, and the width of the resin 9 becomes large. A period of time from when the resin 9 has been supplied to when imprinting is performed may vary in accordance with a position where the shot is performed. Thus, the height (shape) of the resin 9 is estimated in advance based on the period of time from when the resin 9 is supplied to when imprinting is performed. That is, the height of a droplet of the resin 9 is calculated based on a period of time from when the droplet of the resin 9 arrives at the surface of the substrate 10 to when the mold 7 comes into contact with the droplet of the resin 9.

The control unit 6 determines positions (arrangement) of the resin 9 to be supplied to the substrate 10 and/or the amount of each droplet of the resin 9, based on the information acquired in the steps S301 and S302. At a position where the surface height of the substrate 10 is lower than that of the surroundings, there is a possibility that contact between the resin 9 supplied to the substrate 10 and the mold 7 becomes insufficient. Thus, for example, with respect to a position where the surface height of the substrate 10 in the outer peripheral region including the edge of the substrate 10 is lower than the surface height of the substrate 10 in an inner region on a side with the center of the substrate 10 as shown in FIGS. 4A and 4B, the control unit 6 determines that droplets of the resin 9 are not to be supplied. When imprinting is performed on the partial region 101, the mold 7 may be deformed into a convex shape toward the substrate 10 to sufficiently fill the pattern portion 7a with the resin 9. In this case, when the filling of the pattern portion 7a with the resin 9 is completed, a load applied to the mold 7 is released, and the mold 7 in the deformed state is restored. In this process, there may be a position where the resin 9 supplied to the substrate 10 and the mold 7 are not to come into contact with each other. Thus, the control unit 6 determines that the resin 9 is to be supplied at a position where the mold 7, at least in a state not deformed into a convex shape, is to come into contact with the resin 9.

In addition, the control unit 6 may perform determination of whether the resin 9 is to adhere to the mold 7 when the mold 7 is separated from the resin 9 after the mold 7 and a droplet of the resin 9 come into contact with each other in a certain region. For example, the control unit 6 performs a process of determining whether the resin 9 is to adhere to the mold 7 when the mold 7 is separated from the resin 9 after the mold 7 and a droplet of the resin 9 come into contact with each other in the partial region 101. Then, the control unit 6 determines that a droplet of the resin 9 is not supplied to a position where the control unit 6 has determined that the resin 9 is to adhere to the mold 7, and the control unit 6 determines that a droplet of the resin 9 is supplied to a position where the control unit 6 has determined that the resin 9 is not to adhere to the mold 7. Further, for example, the control unit 6 performs a process of determining whether the resin 9 is to come into contact with the mold 7 when the mold 7 in the deformed state is restored to the original state after the resin 9 in the partial region 101 and the mold 7, the pattern region of which has been deformed into a convex shape toward the substrate 10, are brought into contact with each other. Then, the control unit 6 determines that a droplet of the resin 9 is not supplied to a position where the control unit 6 has determined that the resin 9 is not to come into contact with the mold 7, and the control unit 6 determines that a droplet of the resin 9 is supplied to a position where the control unit 6 has determined that the resin 9 is to come into contact with the mold 7.

After the above-described process, the imprint process is completed through a supplying process of supplying the resin 9 to the substrate 10 in step S304, an imprinting process of bringing the mold 7 into contact with the resin 9 in step S305, a curing process of curing the resin 9 in step S306, and a releasing process of separating the mold 7 from the resin 9 in step S307.

While the bend generated in the outer peripheral portion of the substrate 10 due to the suction pressure for holding the substrate 10 has been described, a similar processing procedure is able to be used for a case of a step formed in the outer peripheral portion of the substrate 10 or a case of a bend in the substrate 10 caused by the shape of the substrate chuck 14.

According to the present exemplary embodiment, in imprinting for the shot region, the resin 9′ remaining in the mold 7 is able to be prevented, and defects that may occur when the next shot region is imprinted are able to be reduced. In other words, according to the present exemplary embodiment, adverse effects, such as pattern defects, when imprinting a non-flat substrate is able to be reduced.

Next, an imprint apparatus 1 and an imprint method according to a second exemplary embodiment will be described. In the present exemplary embodiment, descriptions of the same contents as those of the first exemplary embodiment will be omitted, and contents different from those of the first exemplary embodiment will be described. In the first exemplary embodiment, the arrangement or the like of the resin 9 is determined based on the surface height of the substrate 10, whereas in the second exemplary embodiment, a surface shape of the substrate 10 is deformed in accordance with the surface shape of the substrate 10 in such a manner that pattern defects are to be reduced.

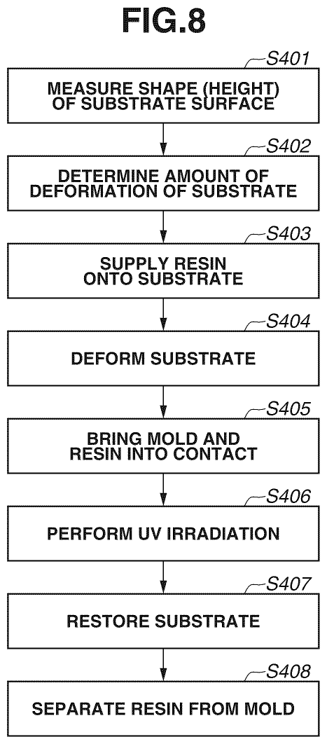

FIG. 8 is a flowchart of an imprint process according to the second exemplary embodiment. While a case in which a shot region to be subjected to the imprint process is the partial region 101 will be described as an example, the present exemplary embodiment can be similarly applied to a case of an imprint process that is performed on the complete region 100.

In step S401, in a state in which the substrate 10 is held by the substrate chuck 14, the surface shape (height) of the partial region 101 of the substrate 10 is measured. In step S402, the control unit 6 determines the deformation amount of the partial region 101 of the substrate 10 from the surface shape of the partial region 101 of the substrate 10. When imprinting is performed on the partial region 101, the mold 7 may be deformed into a convex shape in order to fill the pattern portion 7a with the resin 9. In this case, when the filling of the pattern portion 7a with the resin 9 is completed, the load applied to the mold 7 is released to restore the mold 7 in the deformed state to the original state. In this process, because there may be a position where the resin 9 supplied to the substrate 10 and the mold 7 are not to come into contact with each other, the substrate 10 is deformed such that contact between the mold 7 and the resin 9 is maintained at least in a state in which the mold 7 is not deformed into a convex shape. The control unit 6 determines the deformation amount of the partial region 101 of the substrate 10, based on the measurement data of the surface height of the substrate 10.

In step S403, the resin 9 is supplied to the shot region of the substrate 10.

In step S404, the substrate 10 is deformed based on the determined deformation amount. For example, the surface shape of the substrate 10 in the partial region 101 is deformed based on the measurement data of the surface height of the substrate 10 in such a manner that contact between the resin 9 and the mold 7 is to be maintained when the mold 7 in the deformed state is restored after the resin 9 on the substrate 10 and the mold 7 in the deformed state are brought into contact with each other. Examples of means (substrate deformation unit) for deforming the substrate 10 include means that uses a gas pressure from a gas supply/exhaust mechanism disposed at an outer peripheral portion of the substrate chuck 14. Alternatively, a support unit that drives vertically may be disposed in the substrate chuck 14, to deform the substrate 10 through vertical driving of the support unit. The deformation amount with respect to the gas pressure or the deformation amount with respect to a driving distance of the support unit may be measured in advance. In addition, measurement may be performed to determine whether the substrate 10 is deformed by a predetermined deformation amount, and if the substrate 10 is not deformed by the predetermined deformation amount, adjustment may be performed as needed. In this case, the processing sequence of the step S403 and the step S404 may be changed. Although the subsequent steps are the same as those of the first exemplary embodiment, the substrate 10 in the deformed state is to be restored to the original state in a step S407 before a mold releasing process in step S408. For example, in a case where deformation of the partial region 101 of the substrate 10 is performed with the gas pressure, if restoration of the substrate 10 is not performed, the holding force between the substrate 10 and the substrate chuck 14 may decrease in the mold releasing process in step S408.

While a case of a bend in the partial region 101 of the substrate 10 has been described, a similar processing procedure can be used for a case where a step is formed in the outer peripheral portion of the substrate 10.

According to the above-described exemplary embodiment, the resin 9′ remaining in the mold 7 is able to be prevented in imprinting, and pattern defects are able to be reduced.

Further, the first exemplary embodiment and the second exemplary embodiment may be used in combination. For example, after the surface shape of the substrate 10 is measured, the substrate 10 is deformed, the arrangement of the resin 9 is determined, and the imprint process is performed. This can further prevent the resin 9′ remaining in the mold 7, which reduces occurrence of defects in imprinting that is performed on the shot region of the substrate 10.

### (Method of Manufacturing Article)

As a third exemplary embodiment, a method of manufacturing an article will be described. The pattern formed on the cured product by using the imprint apparatus 1 is permanently used in at least a part of various articles or temporarily used when various articles are manufactured. Examples of the articles include an electric circuit element, an optical element, a micro-electromechanical system (MEMS), a recording element, a sensor, a mold, and the like. Examples of the electric circuit element include a volatile or nonvolatile semiconductor memory, such as a dynamic random-access memory (DRAM), a static random-access memory (SRAM), a flash memory, or a magnetoresistive random access memory (MRAM), and a semiconductor element, such as a large-scale integration (LSI) chip, a charge-coupled device (CCD), an image sensor, or a field programmable gate array (FPGA). Examples of the mold include a mold for imprinting.

The pattern formed on the cured product is used as a constituent member of at least a part of the articles as it is, or is temporarily used as a resist pattern. After etching, ion implantation, or the like is performed in a substrate processing process, the resist pattern is removed.

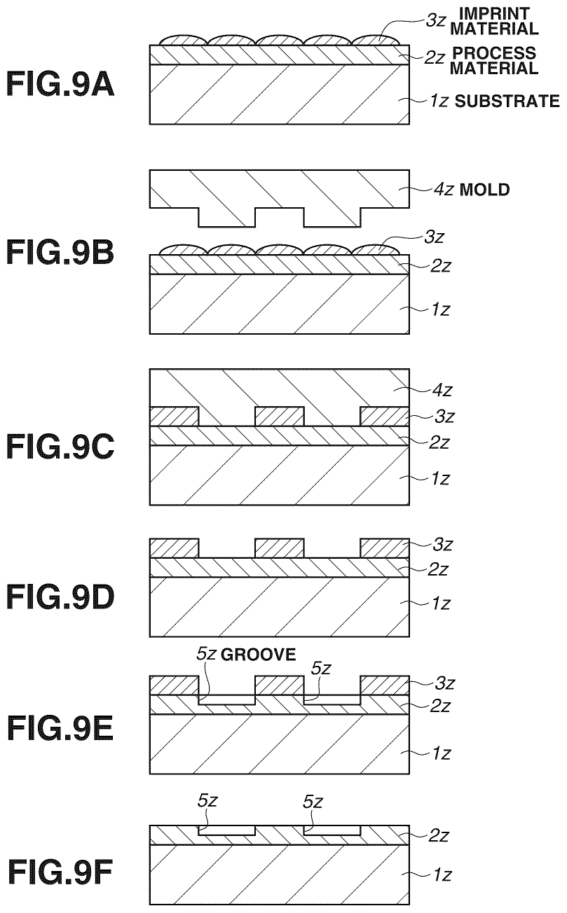

Next, a specific method for manufacturing the articles will be described. As illustrated in FIG. 9A, a substrate 1z, such as a silicon wafer, on which an insulating material or the like as a process material 2z is formed is prepared, and then an imprint material 3z as a process material is applied to the process material 2z by an inkjet method or the like. FIG. 9A illustrates a state in which a plurality of droplets of the photocurable material 3z is applied to the process material 2z on the substrate 1z. The arrangement and the amount of the droplets of the photocurable material 3z are able to be determined by the method described in the first exemplary embodiment.

As shown in FIG. 9B, a mold 4z for imprinting is opposed to the photocurable material 3z applied to the process material 2z on the substrate 1z in a state in which a side of the mold 4z having an uneven pattern faces the photocurable material 3z. As shown in FIG. 9C, the substrate 1z, on which the process material 2z has been formed and the photocurable material 3z has been applied, and the mold 4z are brought into contact with each other and pressurized. The gap between the mold 4z and the process material 2z is filled with the photocurable material 3z. In this process, the substrate 1z may be deformed by the deformation amount determined in the second exemplary embodiment. When light as curing energy is applied through the mold 4z, the photocurable material 3z is cured.

As shown in FIG. 9D, when the mold 4z and the substrate 1z are separated from each other after the photocurable material 3z has been cured, a pattern is formed on a cured product of the photocurable material 3z on the substrate 1z. The pattern of the cured product has a shape in which a depressed portion of the mold 4z corresponds to a projecting portion of the cured product and a depressed portion of the mold 4z corresponds to a projecting portion of the cured product, that is, the uneven pattern of the mold 4z is transferred to the photocurable material 3z.

As shown in FIG. 9E, in etching that is performed using the pattern of the cured product as an etching resistant pattern, a surface portion of the process material 2z where the cured product is absent or thinly remained is removed, and a groove 5z is formed. As illustrated in FIG. 9F, after the pattern of the cured product has been removed, an article having the groove 5z formed on the process material 2z is obtained. While, in the present exemplary embodiment, the pattern of the cured product is removed, the pattern may be used as, for example, a layer for interlayer insulation included in a semiconductor element or the like, that is, the pattern of the cured product can be used as a constituent member of an article without being removed after the processing. As processes other than the above-described process, dicing, bonding, packaging, and the like may also be performed. According to the manufacturing method in the present exemplary embodiment, articles having higher quality than articles manufactured by the related art are able to be manufactured.

Although the exemplary embodiments of the present disclosure have been described above, the present disclosure is not limited to these exemplary embodiments, and various modifications and changes can be made within the scope of the gist of the present disclosure.

The present disclosure can also be realized by processing in which a program for implementing one or more functions of the above-described exemplary embodiments is supplied to a system or an apparatus via a network or a storage medium, and one or more processors in a computer of the system or the apparatus read and execute the program. In addition, the present disclosure can be realized by a circuit (for example, an application specific integrated circuit (ASIC)) that implements one or more functions.

### Other Embodiments

Embodiment(s) of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc™ (BD)), a flash memory device, a memory card, and the like.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2022-190922, filed Nov. 30, 2022, which is hereby incorporated by reference herein in its entirety.

What is claimed is:

1. An imprint apparatus that performs an imprint process of forming a pattern on an imprint material supplied on a substrate by bringing the imprint material into contact with a mold, the imprint apparatus comprising:
a holding unit configured to hold the substrate;
a supply unit configured to supply a droplet of the imprint material to the substrate in a partial region, the partial region including an edge of the substrate and with which a part of a pattern region of the mold is to come into contact in the imprint process; and
a control unit configured to determine a position or an amount of the droplet of the imprint material to be supplied to the partial region, based on measurement data on a surface height of the substrate in the partial region in a state in which the holding unit holds the substrate,
wherein the supply unit supplies the droplet of the imprint material to the partial region, based on the determined position or the determined amount of the droplet of the imprint material, and
wherein the imprint apparatus forms the pattern on the imprint material by bringing the imprint material supplied to the partial region into contact with the mold.

2. The imprint apparatus according to claim 1, wherein the control unit determines the position or the amount of the droplet of the imprint material to be supplied to the partial region, based on the measurement data on the surface height of the substrate in the partial region and a height of the droplet of the imprint material in a state after supply of the imprint material to the substrate.

3. The imprint apparatus according to claim 2, wherein the height of the droplet of the imprint material is calculated based on a period of time from when the droplet of the imprint material reaches a surface of the substrate to when the mold comes into contact with the droplet of the imprint material.

4. The imprint apparatus according to claim 1,
wherein the partial region includes an outer peripheral region including an edge of the substrate and an inner region on a side with a center of the substrate with respect to the outer peripheral region, and
wherein the control unit determines the position of the droplet of the imprint material such that the droplet of the imprint material is not supplied to a position where a surface height of the substrate in the outer peripheral region is lower than a surface height of the substrate in the inner region.

5. The imprint apparatus according to claim 1, further comprising a measurement unit configured to measure the surface height of the substrate in the partial region in a state in which the substrate is held by the holding unit.

6. The imprint apparatus according to claim 1, wherein the measurement data on the surface height of the substrate in the partial region includes information on a surface shape of the substrate in the partial region.

7. The imprint apparatus according to claim 2, wherein the height of the droplet of the imprint material includes information on a shape of the droplet of the imprint material.

8. The imprint apparatus according to claim 1, wherein the control unit determines the position and the amount of the droplet of the imprint material to be supplied to the partial region.

9. An imprint apparatus that performs an imprint process of forming a pattern on an imprint material supplied on a substrate by bringing the imprint material into contact with a mold, the imprint apparatus comprising:
a holding unit configured to hold the substrate;
a supply unit configured to supply a droplet of the imprint material to the substrate in a partial region, the partial region including an edge of the substrate and with which a part of a pattern region of the mold is to come into contact in the imprint process; and
a mold deformation unit configured to deform the pattern region of the mold into a convex shape toward the substrate,
wherein the holding unit includes a substrate deformation unit configured to deform a surface shape of the substrate in the partial region, and
wherein, based on measurement data on a surface height of the substrate in the partial region in a state in which the holding unit holds the substrate, the substrate deformation unit deforms the surface shape of the substrate in the partial region in such a manner that contact between the imprint material and the mold is to be maintained when the mold in a deformed state by the mold deformation unit is restored after the mold in the deformed state has been brought into contact with the imprint material on the substrate.

10. A method of manufacturing an article, the method comprising:
forming, by using an imprint apparatus, a pattern on an imprint material supplied on a substrate in a partial region, the partial region including an edge of the substrate and with which a part of a pattern region of a mold is to come into contact in an imprint process; and
manufacturing the article by processing the substrate on which the pattern has been formed,
wherein the imprint apparatus performs the imprint process of forming the pattern on the imprint material on the substrate by bringing the imprint material into contact with the mold, the imprint apparatus including
a holding unit configured to hold the substrate,
a supply unit configured to supply a droplet of the imprint material to the substrate in the partial region, and
a control unit configured to determine a position or an amount of the droplet of the imprint material to be supplied to the partial region, based on measurement data on a surface height of the substrate in the partial region in a state in which the holding unit holds the substrate,
wherein the supply unit supplies the droplet of the imprint material to the partial region, based on the determined position or the determined amount of the droplet of the imprint material, and
wherein the imprint apparatus forms the pattern on the imprint material by bringing the imprint material supplied to the partial region into contact with the mold.

11. A method of manufacturing an article, the method comprising:
forming, by using an imprint apparatus, a pattern on an imprint material supplied on a substrate in a partial region, the partial region including an edge of the substrate and with which a part of a pattern region of a mold is to come into contact in an imprint process; and
manufacturing the article by processing the substrate on which the pattern has been formed,
wherein the imprint apparatus performs the imprint process of forming the pattern on the imprint material on the substrate by bringing the imprint material into contact with the mold, the imprint apparatus including
a holding unit configured to hold the substrate,
a supply unit configured to supply a droplet of the imprint material to the substrate in the partial region, and
a mold deformation unit configured to deform the pattern region of the mold into a convex shape toward the substrate,
wherein the holding unit includes a substrate deformation unit configured to deform a surface shape of the substrate in the partial region, and
wherein, based on measurement data on a surface height of the substrate in the partial region in a state in which the holding unit holds the substrate, the substrate deformation unit deforms the surface shape of the substrate in the partial region in such a manner that contact between the imprint material and the mold is to be maintained when the mold in a deformed state by the mold deformation unit is restored after the mold in the deformed state has been brought into contact with the imprint material on the substrate.

12. A method for determining a position or an amount of a droplet of an imprint material to be supplied to a substrate for an imprint process in which the imprint material is supplied to the substrate, and the imprint material on the substrate is brought into contact with a mold to form a pattern on the imprint material, the method comprising:
acquiring measurement data obtained by measuring, in a state in which the substrate is held by a holding unit, a surface height of the substrate in a partial region that includes an edge of the substrate and is to come into contact with a part of a pattern region of the mold in the imprint process; and
determining a position or an amount of a droplet of the imprint material to be supplied to the partial region, based on the measurement data on the surface height of the substrate in the partial region.

13. The method according to claim 12, further comprising:
determining whether the imprint material is to adhere to the mold when the mold is separated from the imprint material after the mold and the droplet of the imprint material come into contact with each other in the partial region; and
determining the position of the droplet of the imprint material to be supplied to the partial region by determining not to supply the droplet of the imprint material to a position determined as a position where the imprint material is to adhere to the mold, and determining to supply the droplet of the imprint material to a position determined as a position where the imprint material is not to adhere to the mold.

14. The method according to claim 12, further comprising:
determining whether the imprint material is to come into contact with the mold when the mold in a deformed state is restored after the pattern region of the mold deformed into a convex shape toward the substrate has been brought into contact with the imprint material in the partial region; and
determining the position of the droplet of the imprint material to be supplied to the partial region by determining not to supply the droplet of the imprint material to a position determined as a position where the imprint material is not to come into contact with the mold, and determining to supply the droplet of the imprint material to a position determined as a position where the imprint material is to come into contact with the mold.

15. A non-transitory computer-readable recording medium storing a program for causing a computer to execute a method for determining a position or an amount of a droplet of an imprint material to be supplied to a substrate, the method being for determining the position or the amount of the droplet of the imprint material to be supplied to the substrate for an imprint process in which the imprint material is supplied to the substrate, and the imprint material on the substrate is brought into contact with a mold to form a pattern on the imprint material, the method comprising:
acquiring measurement data obtained by measuring, in a state in which the substrate is held by a holding unit, a surface height of the substrate in a partial region that includes an edge of the substrate and is to come into contact with a part of a pattern region of the mold in the imprint process; and
determining the position or an amount of a droplet of the imprint material to be supplied to the partial region, based on the measurement data on the surface height of the substrate in the partial region.
